(19) United States
(12) Patent Application Publication
(10) Pub. No.: US 2026/0052810 A1
(43) Pub. Date: Feb. 19, 2026

(54) DISPLAY DEVICE AND MANUFACTURING METHOD THEREOF

(71) Applicant: AUO Corporation, Hsinchu City (TW)

(72) Inventors: YinYu Chen, Hsinchu City (TW); Yi-Hong Chen, Hsinchu City (TW); Chia-An Lee, Hsinchu City (TW); Yu-Hsin Huang, Hsinchu City (TW); Wen-Wei Yang, Hsinchu City (TW); Kuan-Heng Lin, Hsinchu City (TW)

(73) Assignee: AUO Corporation, Hsinchu City (TW)

(21) Appl. No.: 18/954,496

(22) Filed: Nov. 20, 2024

(30) Foreign Application Priority Data
Aug. 13, 2024 (TW) 113130297

(51) Int. Cl. H01L 33/50; H01L 25/16; H01L 33/60; H01L 33/62

(52) U.S. Cl. CPC H10H 20/8514; H01L 25/167; H10H 20/856; H10H 20/857; H10H 20/0361; H10H 20/0364

(57) ABSTRACT

A display device including a plurality of display pixels is provided. Each of the display pixels includes at least one first light-emitting unit. The first light-emitting unit includes a first light-emitting diode and a color conversion layer. The first light-emitting diode is disposed on a substrate, and includes a first pad, a first semiconductor layer, a first light-emitting layer, a second semiconductor layer, and a second pad that are sequentially stacked. The color conversion layer surrounds the first light-emitting diode. A top surface of the color conversion layer is lower than a top surface of the second pad, or is coplanar with the top surface of the second pad. A manufacturing method of the display device is also provided.

### CROSS-REFERENCE TO RELATED APPLICATION

This application claims the priority benefit of Taiwan application serial no. 113130297, filed on Aug. 13, 2024. The entirety of the above-mentioned patent application is hereby incorporated by reference herein and made a part of this specification.

### BACKGROUND

### Technical Field

The disclosure relates to a display device and a manufacturing method thereof.

### Description of Related Art

The manufacturing process of a light-emitting diode display includes multiple flipping of the crystal grains. The flipping process requires the use of a colloid layer to fix the crystal grains, and finally the colloid layer needs to be removed. Moreover, if it is necessary to use a color conversion layer for color conversion, after the crystal grain is transferred to the back sheet, an additional process must be used to dispose a colloid layer 201A containing the color conversion particles as shown in FIG. 1.

### SUMMARY

The disclosure provides a display device and a manufacturing method thereof, which greatly shortens the manufacturing time.

According to an embodiment of the disclosure, a display device is provided, including a substrate and a plurality of display pixels disposed on the substrate, where each display pixel includes a plurality of light-emitting units. The light-emitting units include at least one first light-emitting unit, and the first light-emitting unit includes a first light-emitting diode and a color conversion layer. The first light-emitting diode is disposed on the substrate and includes a first pad, a first semiconductor layer, a first light-emitting layer, a second semiconductor layer, and a second pad that are sequentially stacked. The first pad is connected to the first semiconductor layer, and the second pad is connected to the second semiconductor layer. The color conversion layer surrounds the first light-emitting diode. A top surface of the color conversion layer is lower than a top surface of the second pad, or is coplanar with the top surface of the second pad.

According to an embodiment of the disclosure, a display device manufacturing method is provided, including sequentially disposing a second semiconductor layer, a light-emitting layer, a first semiconductor layer, and a first pad on a temporary substrate, where the first pad is connected to the first semiconductor layer; sequentially disposing an adhesive layer and a substrate on the temporary substrate, where the adhesive layer includes color conversion particles and surrounds the light-emitting layer, and the substrate is bonded to the first pad; removing the temporary substrate; disposing a second pad on the second semiconductor layer; and completing the first light-emitting unit.

Based on the above, the display device manufacturing method provided by the embodiment of the disclosure disposes color conversion particles in the adhesive layer used to fix the first light-emitting diode. Therefore, the adhesive layer does not need to be removed during the manufacturing process, and the adhesive layer may be used as the color conversion layer of the display device. No additional process is required to dispose the color conversion layer, and the process time is significantly shortened compared to the conventional art.

In order to make the above-mentioned features and advantages of the disclosure clearer and easier to understand, the following embodiments are given and described in details with accompanying drawings as follows.

### BRIEF DESCRIPTION OF THE DRAWINGS

FIG. 1 is a schematic diagram of a light-emitting unit according to the conventional art.

FIG. 2A to FIG. 2D are schematic diagrams of a display device manufacturing method according to an embodiment of the disclosure.

FIG. 3A to FIG. 3C are schematic diagrams of a light-emitting unit according to some embodiments of the disclosure, and FIG. 3D shows relative reflectivity curves of light on different components.

FIG. 4 is a schematic diagram of a light-emitting unit according to some embodiments of the disclosure.

FIG. 5 is a schematic diagram of a light-emitting unit according to some embodiments of the disclosure.

FIG. 6A is a schematic diagram of a light-emitting unit according to some embodiments of the disclosure, and FIG. 6B is a schematic diagram of a display pixel of a display device according to an embodiment of the disclosure.

FIG. 7 is a schematic diagram of a display pixel of a display device according to an embodiment of the disclosure.

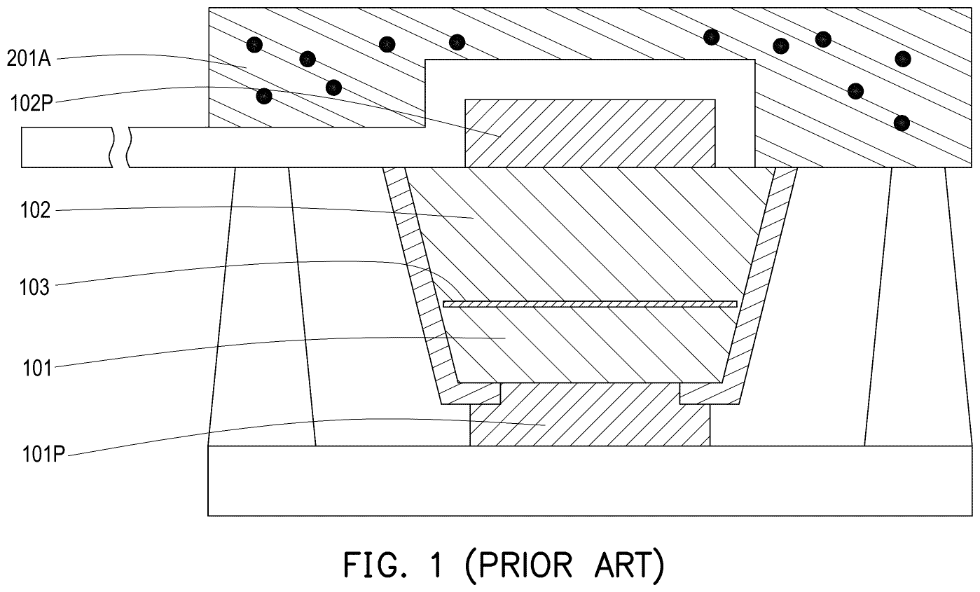

### DESCRIPTION OF THE EMBODIMENTS

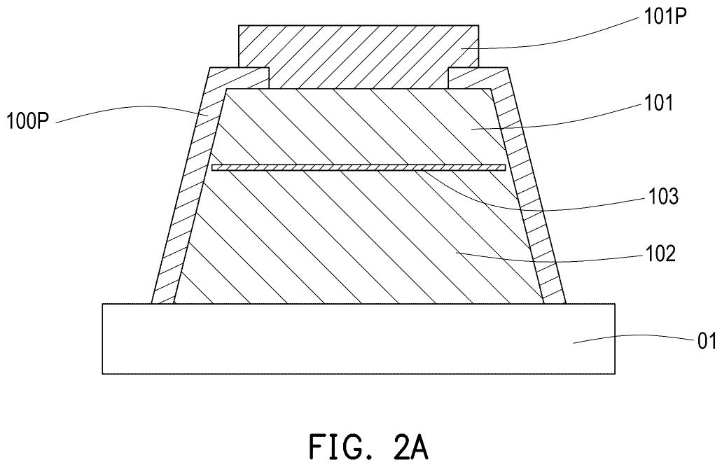

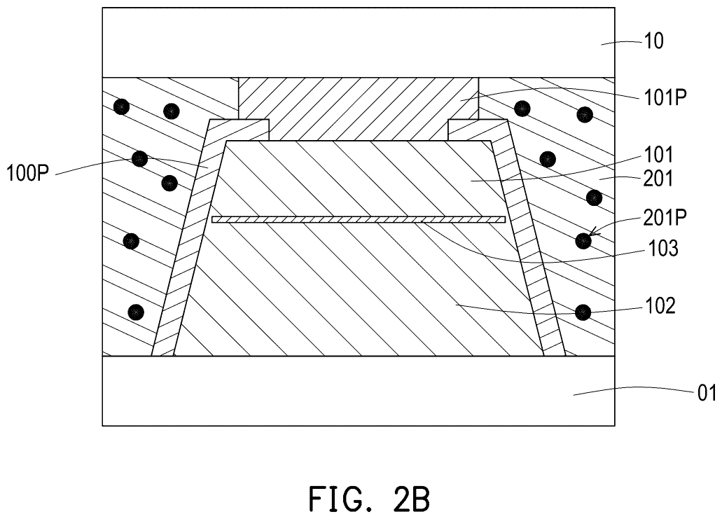

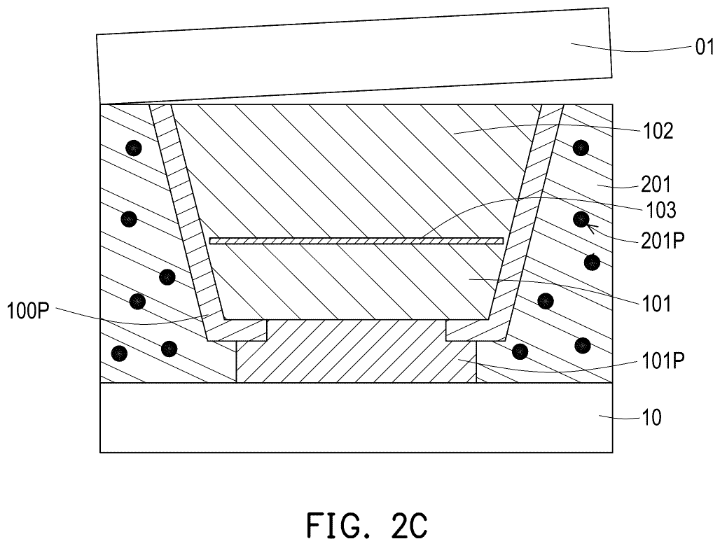

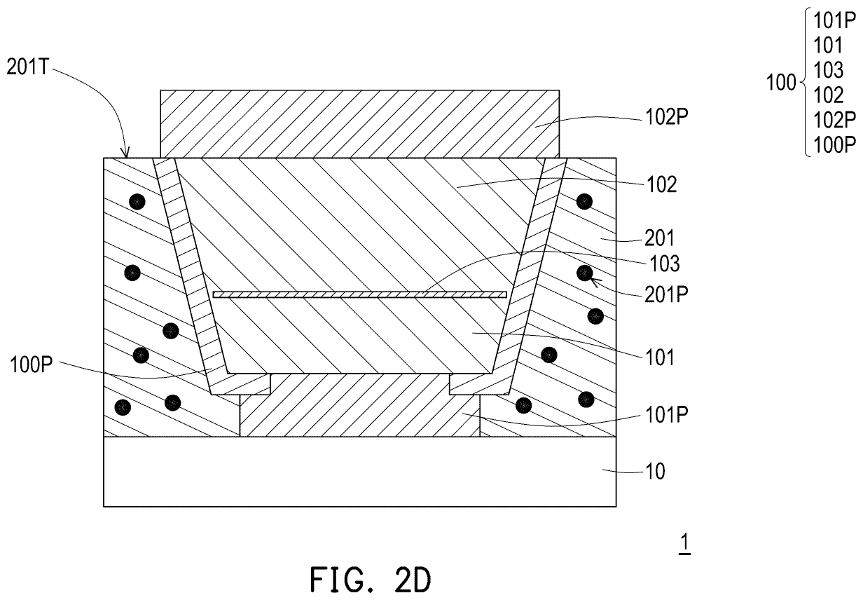

Referring to FIG. 2A to FIG. 2D, schematic diagrams of a display device manufacturing method according to an embodiment of the disclosure are shown in sequence.

As shown in FIG. 2A, a second semiconductor layer 102, a light-emitting layer 103, a first semiconductor layer 101, and a first pad 101P are sequentially disposed on a temporary substrate 01, where the first pad 101P is connected to the first semiconductor layer 101.

As shown in FIG. 2B, an adhesive layer 201 is disposed on the temporary substrate 01 to fix the second semiconductor layer 102, the light-emitting layer 103, the first semiconductor layer 101, and the first pad 101P. It should be particularly noted that the adhesive layer 201 includes color conversion particles 201P; and a substrate 10 is disposed on the first pad 101P and the adhesive layer 201, where the first pad 101P is bonded to the substrate 10.

As shown in FIG. 2C, the structure in FIG. 2B is turned over, and the temporary substrate 01 is removed.

As shown in FIG. 2D, a second pad 102P is disposed on the second semiconductor layer 102 to form a light-emitting unit 1. The area of the vertical projection of the second pad 102P on the second semiconductor layer 102 is not zero. The light-emitting unit 1 includes a first light-emitting diode 100 and the adhesive layer 201 surrounding the first light-emitting diode 100. The first light-emitting diode 100 includes the first pad 101P, the first semiconductor layer 101, the light-emitting layer 103, the second semiconductor layer 102, and the second pad 102P.

It should be noted that compared with the conventional art, the display device manufacturing method according to the embodiment does not require removal of the adhesive layer 201 used to fix the first light-emitting diode 100, nor does it require other processes for disposing the color conversion layer, which significantly shortens the manufacturing time compared to the conventional art. Specifically, as shown in FIG. 2D, since the adhesive layer 201 surrounds the first light-emitting diode 100, the light emitted from the light-emitting layer 103 may be color converted by the color conversion particles 201P in the adhesive layer 201. In other words, the adhesive layer 201 may be used as the color conversion layer of the first light-emitting diode 100 (i.e., the color conversion layer 201). It should also be noted that through the above-mentioned manufacturing method shown in FIG. 2A to FIG. 2D, a top surface 201T of the color conversion layer 201 away from the substrate 10 is coplanar with the top surface of the second semiconductor layer 102 away from the substrate 10 and lower than the top surface of the second pad 102P away from the substrate 10.

However, the disclosure is not limited thereto. In some embodiments not shown, an adhesive layer with the same material as the color conversion layer 201 may also be disposed on the top surface 201T shown in FIG. 2D to increase the thickness of the color conversion layer 201 and improve the color conversion rate. In the embodiments, the top surface of the color conversion layer 201 away from the substrate 10 may be coplanar with the top surface of the second pad 102P away from the substrate 10. In some embodiments not shown, part of the color conversion layer 201 may be removed, so that the top surface of the color conversion layer 201 away from the substrate 10 is lower than the top surface of the second semiconductor layer 102 away from the substrate 10.

Through the display device manufacturing method provided by the above embodiment, some embodiments of the disclosure provide a display device. The display device includes a plurality of display pixels, and each display pixel may include a plurality of light-emitting units. At least one of the light-emitting units may be the light-emitting unit 1 as shown in FIG. 2D. The light-emitting unit 1 includes the first light-emitting diode 100 and the color conversion layer 201 surrounding the first light-emitting diode 100. Each first light-emitting diode 100 includes the first pad 101P, the first semiconductor layer 101, the light-emitting layer 103, the second semiconductor layer 102, and the second pad 102P. In some embodiments, the top surface 201T of the color conversion layer 201 away from the substrate 10 may be coplanar with the top surface of the second semiconductor layer 102 away from the substrate 10 and lower than the top surface of the second pad 102P away from the substrate 10. In some embodiments, the top surface of the color conversion layer 201 away from the substrate 10 may be coplanar with the top surface of the second pad 102P away from the substrate 10. In some embodiments, the top surface of the color conversion layer 201 away from the substrate 10 may be lower than the top surface of the second semiconductor layer 102 away from the substrate 10. It should be noted that, in order to ensure that the light emitted by the light-emitting layer 103 may be color converted by the color conversion layer 201, the top surface of the second semiconductor layer 102 away from the substrate 10 is completely covered by the second pad 102P. Accordingly, the second pad 102P may reflect the light that is emitted from the light-emitting layer 103 and does not pass through the color conversion layer 201, thereby improving the color conversion rate and ensuring the display quality of the display device.

In some embodiments, the light-emitting layer 103 in the light-emitting unit 1 may emit blue light, and the color conversion layer 201 is adapted to convert the blue light into red light or green light. In the embodiments, each display pixel may include at least one light-emitting unit without the color conversion layer 201 for emitting blue light.

In some embodiments, the light-emitting layer 103 may emit ultraviolet light, and the color conversion layer 201 is adapted to convert the ultraviolet light into red light, green light, or blue light.

To sufficiently describe various implementation examples and aspects of the disclosure, several other embodiments of the disclosure are described below. Note that the reference numerals and a part of the contents in the previous embodiment are applicable to the following embodiments, in which identical reference numerals indicate identical or similar components, and repeated descriptions of the same technical contents are omitted. For the detailed descriptions of the omitted parts, reference can be found in the previous embodiment, and no repeated description is contained in the following embodiments.

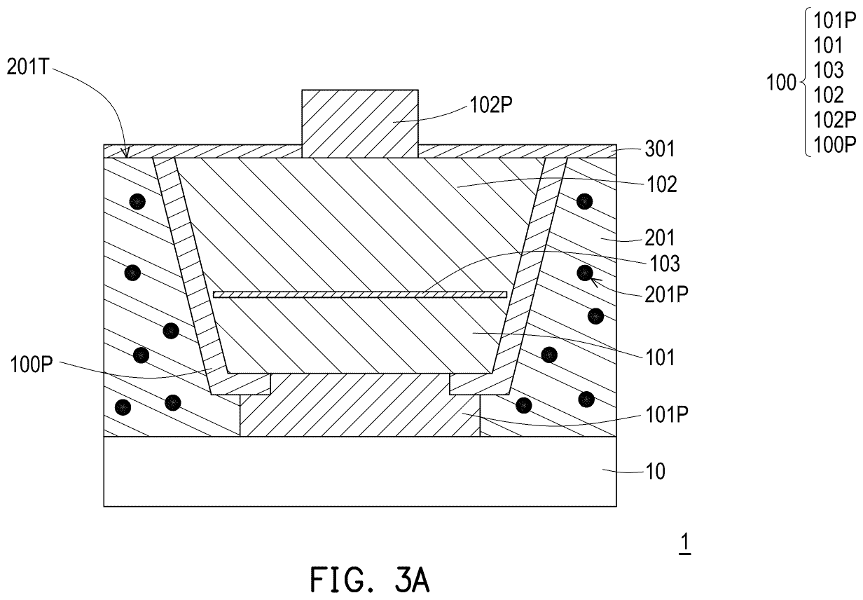

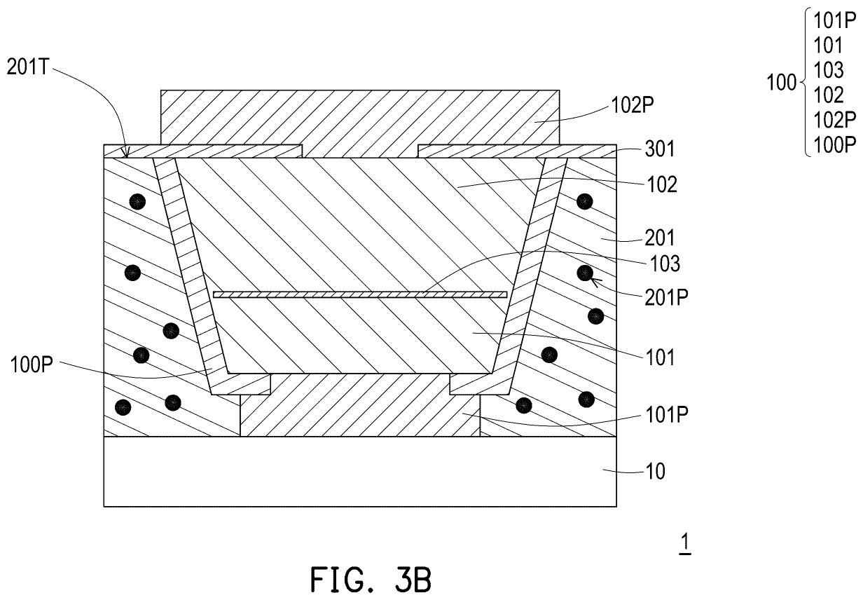

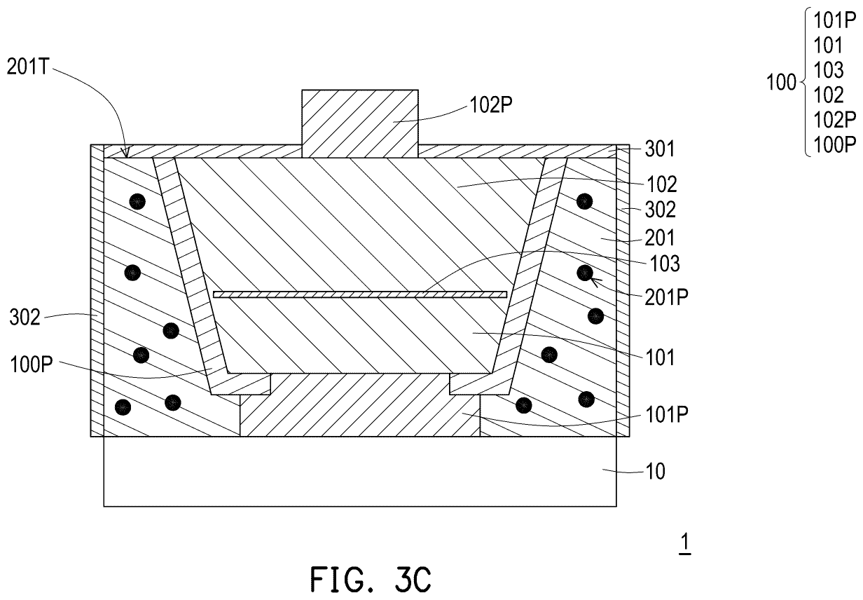

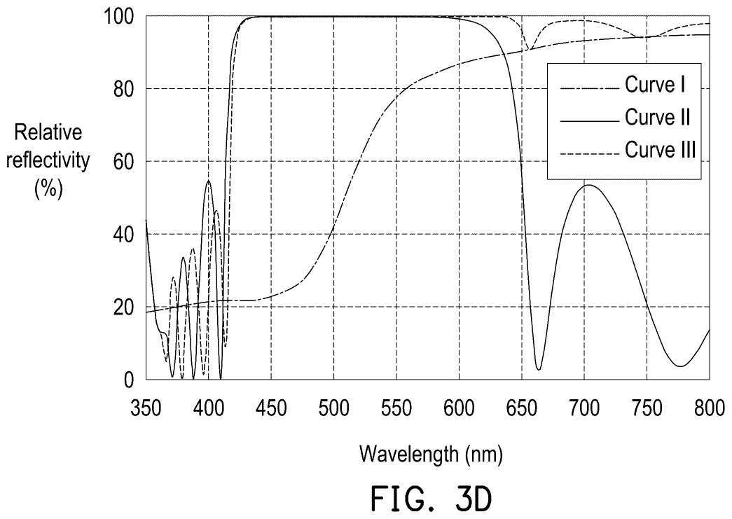

Next, referring to FIG. 3A to FIG. 3D, FIG. 3A to FIG. 3C are schematic diagrams of a light-emitting unit according to some embodiments of the disclosure, and FIG. 3D shows relative reflectivity curves of light on different components.

Compared with the light-emitting unit 1 shown in FIG. 2D, in the light-emitting unit 1 shown in FIG. 3A, a distributed Bragg reflector 301 is disposed on part of the top surface of the second semiconductor layer 102 away from the substrate 10 and the top surface 201T of the color conversion layer 201 away from the substrate 10. The distributed Bragg reflector 301 is adapted to reflect the light that is emitted from the light-emitting layer 103 and does not pass through the color conversion layer 201, and allows the light emitted from the light-emitting layer 103 and color-converted by the color conversion layer 201 to pass.

Referring to FIG. 3D first, Curve I shows the relative reflectivity of light of different wavelengths when reflected on the second pad 102P made of gold (Au), and Curve II shows the relative reflectivity of light of different wavelengths when reflected on the distributed Bragg reflector 301. It can be seen that when the blue light wavelength band is reflected on the second pad 102P made of gold (Au), the blue light wavelength band has a lower reflectivity compared to other color light wavelength bands. In addition, since the distributed Bragg reflector 301 uses the interference phenomenon caused by layers with different refractive indexes to enhance the reflectivity, the distributed Bragg reflector 301 has the disadvantage of low reflectivity of incident light at large angles. Referring to FIG. 3B and FIG. 3D at the same time, compared with the light-emitting unit 1 of FIG. 3A, in the light-emitting unit 1 shown in FIG. 3B, the distributed Bragg reflector 301 is disposed on part of the top surface of the second semiconductor layer 102 away from the substrate 10 and on the top surface 201T of the color conversion layer 201 away from the substrate 10, and the distributed Bragg reflector 301 overlaps the second pad 102P on part of the top surface of the second semiconductor layer 102. Referring to Curve III of FIG. 3D, it shows the relative reflectivity of light of different wavelengths in the above-mentioned overlapping area. It can be seen that the light in the visible light wavelength band has high reflectivity in the above-mentioned overlapping area. In other words, the light-emitting unit 1 shown in FIG. 3B may effectively prevent the light that is emitted from the light-emitting layer 103 and does not pass through the color conversion layer 201 from being emitted upward through the above-mentioned distributed Bragg reflector 301 and the second pad 102P, thereby improving the color conversion rate and ensuring the display quality of the display device.

Compared with the light-emitting unit 1 shown in FIG. 3A, in the light-emitting unit 1 shown in FIG. 3C, a color resist layer 302 is also disposed on the side of the color conversion layer 201. The color resist layer 302 corresponds to the color conversion layer 201 and filters the light that is color converted by the color conversion layer 201 to further ensure the display quality of the display device. In addition, by disposing the color resist layer 302 on the side of the color conversion layer 201, there is no need to dispose a bank between the light-emitting unit 1 and adjacent light-emitting units of other colors in the display device.

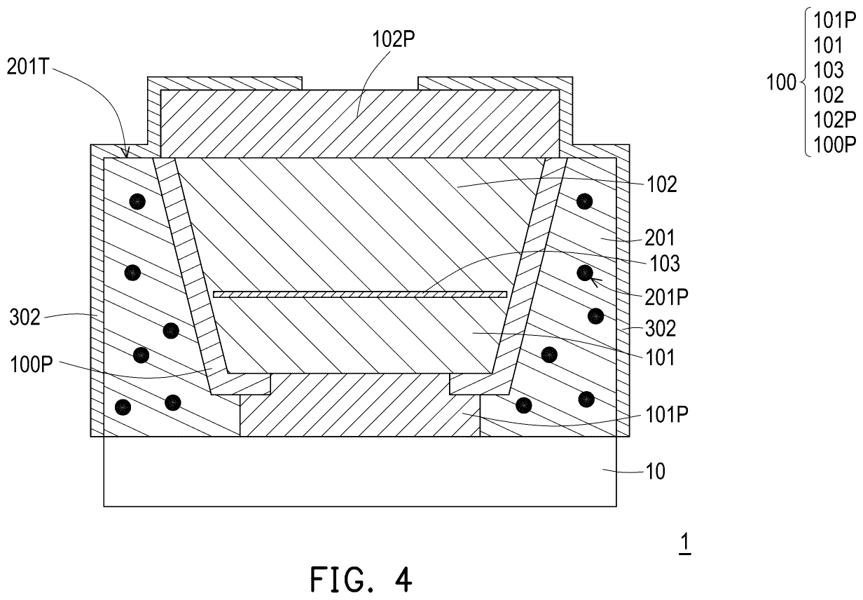

Referring to FIG. 4, FIG. 4 is a schematic diagram of a light-emitting unit according to some embodiments of the disclosure. Compared with the light-emitting unit 1 shown in FIG. 2D, in the light-emitting unit 1 shown in FIG. 4, the color resist layer 302 is disposed on the top surface 201T of the color conversion layer 201 away from the substrate 10, on the sides of the color conversion layer 201, on part of the top surface of the second pad 102P away from the substrate 10, and on the sides of the second pad 102P. The color resist layer 302 corresponds to the color conversion layer 201 to further filter light so as to ensure the display quality of the display device. By disposing the color resist layer 302 on the sides of the color conversion layer 201, there is no need to dispose a bank between the light-emitting unit 1 and adjacent light-emitting units of other colors in the display device.

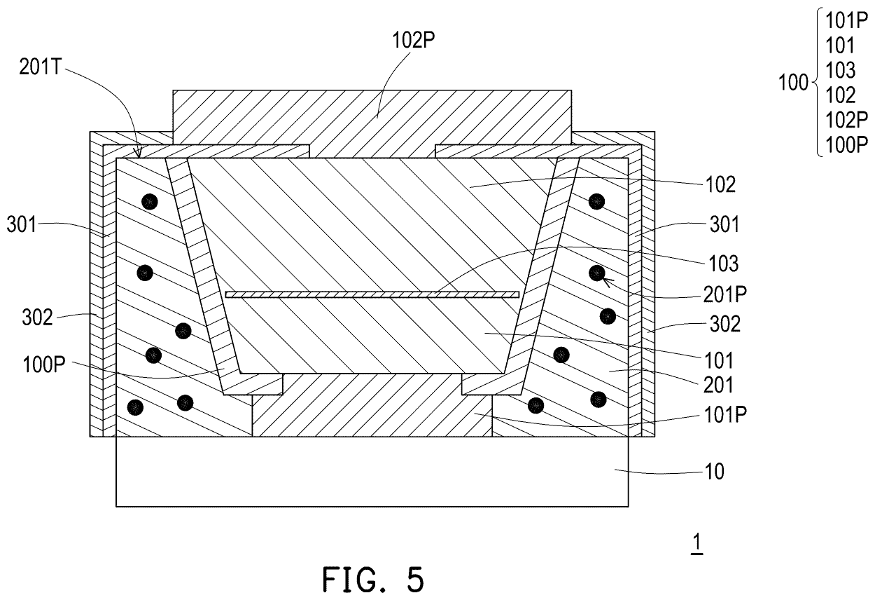

Referring to FIG. 5, FIG. 5 is a schematic diagram of a light-emitting unit according to some embodiments of the disclosure. Compared with the light-emitting unit 1 shown in FIG. 2D, in the light-emitting unit 1 shown in FIG. 5, the distributed Bragg reflector 301 is disposed on part of the top surface of the second semiconductor layer 102 away from the substrate 10, on the top surface 201T of the color conversion layer 201 away from the substrate 10, and on the sides of the color conversion layer 201. The distributed Bragg reflector 301 is adapted to reflect the light that is emitted from the light-emitting layer 103 and does not pass through the color conversion layer 201, and allows the light that is emitted from the light-emitting layer 103 and color-converted by the color conversion layer 201 to pass. In addition, the color resist layer 302 is also disposed on the surface of the distributed Bragg reflector 301 away from the color conversion layer 201. The color resist layer 302 corresponds to the color conversion layer 201, and the color resist layer 302 is adapted to filter the light that is color converted by the color conversion layer 201 and passes through the distributed Bragg reflector 301 so as to further ensure the display quality of the display device. In addition, by disposing the distributed Bragg reflector 301 and the color resist layer 302 on the sides of the color conversion layer 201, there is no need to dispose a bank between the light-emitting unit 1 and adjacent light-emitting units of other colors in the display device.

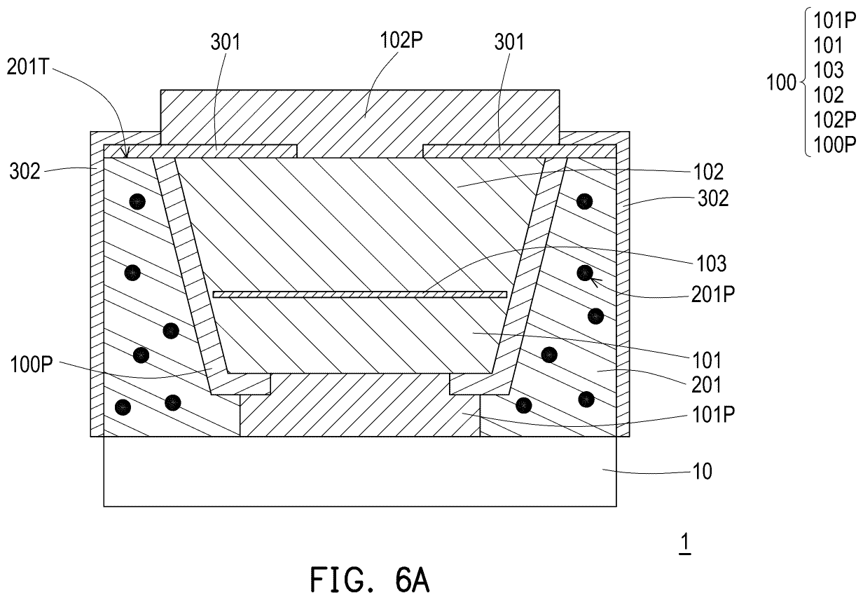

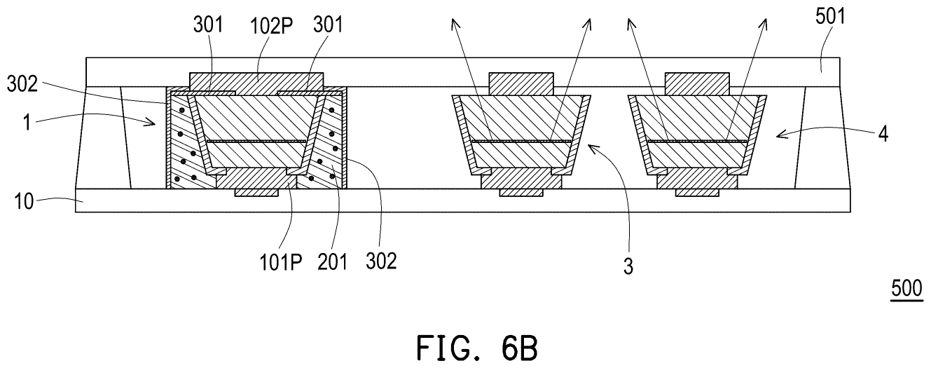

Referring to FIG. 6A, FIG. 6A is a schematic diagram of a light-emitting unit according to some embodiments of the disclosure. Compared with the light-emitting unit 1 shown in FIG. 5, in the light-emitting unit 1 shown in FIG. 6A, the color resist layer 302 is disposed on the sides of the color conversion layer 201, but the distributed Bragg reflector 301 is not disposed. Referring to FIG. 6B, FIG. 6B is a schematic diagram of a display pixel of a display device 500 provided according to an embodiment of the disclosure. The display device 500 includes a plurality of display pixels, and each display pixel may include the light-emitting unit 1, a light-emitting unit 3, and a light-emitting unit 4. The light-emitting unit 1 may be implemented by the light-emitting unit 1 shown in FIG. 6A. However, the disclosure is not limited thereto. The light-emitting unit 1 in FIG. 6B may also be implemented by the light-emitting unit 1 shown in any one of FIG. 2D, FIG. 3A, FIG. 3B, FIG. 3C, FIG. 4, and FIG. 5. In FIG. 6B, the light-emitting unit 3 and the light-emitting unit 4 do not include a color conversion layer. In some embodiments, the light-emitting unit 1 may be used to generate red light, the light-emitting unit 3 may be used to generate green light, and the light-emitting unit 4 may be used to generate blue light, but is not limited thereto. It should be noted that since the color resist layer 302 is disposed on the sides of the color conversion layer 201 of the light-emitting unit 1, crosstalk between the light-emitting unit 1 and adjacent light-emitting units of other colors (such as the light-emitting unit 3) in the display device 500 may be avoided. There is no need to provide a bank between two light-emitting units.

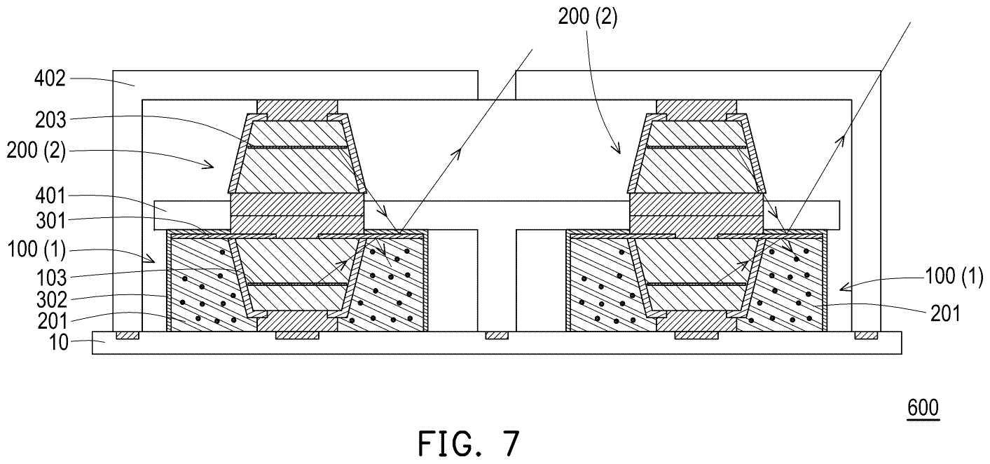

Referring to FIG. 7, FIG. 7 is a schematic diagram of a display pixel of a display device 600 according to an embodiment of the disclosure. The display device 600 includes a plurality of display pixels, and each display pixel may include two light-emitting units 1 and two light-emitting units 2 respectively located on the two light-emitting units 1. The two light-emitting units 1 may be implemented by the light-emitting unit 1 shown in any one of FIG. 2D, FIG. 3A, FIG. 3B, FIG. 3C, FIG. 4, FIG. 5, and FIG. 6A. Either one of the two light-emitting units 2 has a second light-emitting diode 200 having a similar structure to the aforementioned first light-emitting diode 100. The second light-emitting diode 200 includes a light-emitting layer 203, and the second light-emitting diode 200 in each light-emitting unit 2 is not surrounded by the color conversion layer 201.

In an exemplary embodiment, the color conversion layer 201 in each light-emitting unit 1 is adapted to convert blue light emitted by the light-emitting layer 103 that it surrounds into red light. One of the two light-emitting units 2 may emit blue light, and the other may emit green light. The distributed Bragg reflector 301 in the light-emitting unit 1 is adapted to reflect blue light and green light.

In an exemplary embodiment, the color conversion layer 201 in each light-emitting unit 1 is adapted to convert blue light emitted by the light-emitting layer 103 it surrounds into green light. One of the two light-emitting units 2 may emit blue light, and the other may emit red light. The distributed Bragg reflector 301 in the light-emitting unit 1 is adapted to reflect blue light and red light.

It should be noted that compared with the conventional art where the light-emitting unit 1 and the light-emitting unit 2 are disposed at the same level, the embodiment greatly increases space utilization by stacking the light-emitting unit 2 on the light-emitting unit 1, thereby reducing the area occupied by each display pixel on the substrate 10, and improving the resolution of the display device 600.

It should also be noted that, as shown in FIG. 7, the vertical projection of the light-emitting layer 203 on the substrate 10 overlaps the vertical projection of the light-emitting layer 103 on the substrate 10, and at least a part of the vertical projection of the light-emitting layer 203 on the substrate 10 does not overlap the vertical projection of the color conversion layer 201 on the substrate 10. Accordingly, the light-emitting layer 203 of the light-emitting unit 2 does not block the light from the color conversion layer 201, and the distributed Bragg reflector 301 in the light-emitting unit 1 is adapted to reflect the light emitted by the light-emitting layer 203 of the light-emitting unit 2, thereby reducing energy loss. In addition, since the color resist layer 302 is disposed on the side of the color conversion layer 201 of the light-emitting unit 1, a bank may not be disposed between the light-emitting unit 1 and other adjacent light-emitting units.

It should be noted that the above-mentioned display device 600 is a single-board structure, which may be completed by sequentially disposing a plurality of light-emitting units 1, a transparent conductive layer 401, a plurality of light-emitting units 2, and a conductive layer 402 on the substrate 10. The transparent conductive layer 401 is used as a common electrode layer of each light-emitting unit 1 and each light-emitting unit 2. The conductive layer 402 may be a transparent conductive layer or a metal layer, and is electrically connected to the substrate 10. In another embodiment, the light-emitting units 1 and the light-emitting units 2 may be combined by a double-board pairing, and are not limited to the structure shown in FIG. 7.

In summary, the display device manufacturing method provided by the embodiment of the disclosure disposes color conversion particles in the adhesive layer used to fix the first light-emitting diode. Therefore, the adhesive layer does not need to be removed during the manufacturing process, and the adhesive layer may be used as the color conversion layer of the display device. No additional process is required to dispose the color conversion layer, and the process time is significantly shortened compared to the conventional art.

What is claimed is:

1. A display device comprising a substrate and a plurality of display pixels disposed on the substrate, wherein each of the display pixels comprises a plurality of light-emitting units, the plurality of light-emitting units comprise at least one first light-emitting unit, and the at least one first light-emitting unit comprises:
a first light-emitting diode, disposed on the substrate, and comprising a first pad, a first semiconductor layer, a first light-emitting layer, a second semiconductor layer, and a second pad that are sequentially stacked, wherein the first pad is connected to the first semiconductor layer, and the second pad is connected to the second semiconductor layer; and
a color conversion layer, surrounding the first light-emitting diode, wherein
a top surface of the color conversion layer is lower than a top surface of the second pad, or is coplanar with the top surface of the second pad.

2. The display device according to claim 1, wherein the top surface of the color conversion layer is coplanar with a top surface of the second semiconductor layer.

3. The display device according to claim 1, wherein the top surface of the color conversion layer is lower than a top surface of the second semiconductor layer.

4. The display device according to claim 1, wherein a color resist layer is disposed on at least one surface of the color conversion layer.

5. The display device according to claim 1, wherein a distributed Bragg reflector is disposed on at least one surface of the color conversion layer.

6. The display device according to claim 5, wherein the distributed Bragg reflector is disposed on a top surface of the second semiconductor layer.

7. The display device according to claim 6, wherein the distributed Bragg reflector is disposed to be overlapped with the second pad.

8. The display device according to claim 7, wherein a color resist layer is disposed on at least one surface of the color conversion layer, and the distributed Bragg reflector is located on the color conversion layer and the color resist layer.

9. The display device according to claim 1, wherein the first light-emitting layer emits blue light.

10. The display device according to claim 1, wherein the first light-emitting layer emits ultraviolet light.

11. The display device according to claim 1, wherein the plurality of light-emitting units comprises at least one second light-emitting unit, and the at least one second light-emitting unit is disposed on the at least one first light-emitting unit.

12. The display device according to claim 11, wherein the at least one second light-emitting unit comprises a second light-emitting layer, and a vertical projection of the second light-emitting layer on the substrate overlaps a vertical projection of the first light-emitting layer of the at least one first light-emitting unit on the substrate.

13. The display device according to claim 11, wherein the at least one second light-emitting unit comprises a second light-emitting layer, and at least a part of a vertical projection of the second light-emitting layer on the substrate does not overlap a vertical projection of the color conversion layer of the corresponding at least one first light-emitting unit on the substrate.

14. A display device manufacturing method, comprising:
sequentially disposing a second semiconductor layer, a light-emitting layer, a first semiconductor layer, and a first pad on a temporary substrate, wherein the first pad is connected to the first semiconductor layer;
sequentially disposing an adhesive layer and a substrate on the temporary substrate, wherein the adhesive layer comprises color conversion particles and surrounds the light-emitting layer, and the substrate is bonded to the first pad;
removing the temporary substrate;
disposing a second pad on the second semiconductor layer; and
completing the first light-emitting unit.

15. The display device manufacturing method according to claim 14, further comprising:
disposing a transparent conductive layer on the first light-emitting unit; and
disposing a second light-emitting unit on the transparent conductive layer, wherein the transparent conductive layer is a common electrode layer of the first light-emitting unit and the second light-emitting unit.
